(19) United States
(12) Patent Application Publication
(10) Pub. No.: US 2002/0113300 A1
(43) Pub. Date: Aug. 22, 2002

(54) System and method for suppressing RF resonance in a semiconductor package

(76) Inventors: Mindaugas F. Dautartas, Blacksburg, VA (US); Joseph M. Freund, Fogelsville, PA (US); John M. Geary, Macungie, PA (US)

Correspondence Address: DICKSTEIN SHAPIRO MORIN & OSHINSKY LLP, 2101 L STREET NW, WASHINGTON, DC, 20037-1526, US

(21) Appl. No.: 09/781,994

(22) Filed: Feb. 14, 2001

(51) Int. Cl. H01L 23/02; H01L 23/34

(52) U.S. Cl. 257/678; 257/704; 257/714

(57) ABSTRACT

A system and method for optimizing the output of a semiconductor die is described. A lid for a semiconductor package includes a radio frequency resonance dampening material which can be repatterned in real time to minimize resonance reflection within the package. The patterning may take the form of structures within the material or different sections of the material having differing resistivities to resonance reflection. Upon determing that acceptable resonance reflection has been achieved, the material is cured.

### FIELD OF THE INVENTION

The invention generally relates to the suppression of radio frequency resonance in the packaging of semiconductor dies or chips.

### BACKGROUND

The packaging of semiconductor dies is well known. High speed dies used in optoelectric applications are typically coupled electrically and physically to a thermoelectric cooling (TEC) device. Specifically, high speed dies are typically attached to a submount, which in turn is physically coupled to the TEC device. A high speed connector, which is electrically connected with the die, leads from the submount to connect the die with a semiconductor device.

It is standard practice to house the die, submount and TEC device within a package. The package provides physical protection to the die, submount, TEC device and attendant connectors. The electrical current that flows into the die, however, can create a radio frequency (RF) resonance. The RF resonance may degrade the performance of the die, and hence the overall performance of the semiconductor device.

The side walls of some known packages have been coated with an RF resonance dampening material, such as a carbon-filled epoxy. One disadvantage to this is that after coating the side walls, curing the coating, and attaching the TEC device to a floor of the package, it may be determined that the RF resonance dampening material may not affect, or may insufficiently affect, the deleterious effects of the RF resonance. However, with known packages, the die, submount and TEC device must be removed from the package and either a new RF resonance dampening material must be added to the side walls of the package, a new pattern must be put in the material already on the side walls, or a new package must be used. However, there is no guarantee that the alteration of the RF resonance dampening material, or the new package, will be sufficiently effective to suppress the RF resonance to acceptably low levels. If the alteration is not sufficiently effective, the die, submount, and TEC device must again be removed from the package. Removal of the die, submount, and TEC device is time consuming and increases the costs of semiconductor packaging.

### SUMMARY

The invention provides a semiconductor package that includes a package body having a cavity, a die being located within the cavity, and a package lid for closing the cavity. The lid has a radio frequency resonance dampening material applied to an undersurface thereof.

In one aspect of the invention, the semiconductor package includes a submount and a die mounted on the submount. The die and submount are located within the cavity. The lid allows for easy access to the packaged devices and quick and easy replacement and/or modification of the dampening material.

These and other advantages and features of the invention will be more readily understood from the following detailed description which is provided in connection with the accompanying drawings.

### BRIEF DESCRIPTION OF THE DRAWINGS

FIG. 1 is a top view of a semiconductor package constructed in accordance with an embodiment of the invention.

FIG. 2 is a cross-sectional view taken along line II-II of the semiconductor package of FIG. 1.

FIG. 3 is a bottom view of a package lid constructed in accordance with another embodiment of the invention.

FIG. 4 is a cross-sectional view taken along line IV-IV of the package lid of FIG. 3.

FIG. 5 is a bottom view of a package lid constructed in accordance with another embodiment of the invention.

FIG. 6 is a bottom view of a package lid constructed in accordance with another embodiment of the invention.

FIG. 7 is a cross-sectional view taken along line VII-VII of the package lid of FIG. 6

FIG. 8 is an alternative cross-sectional view taken along line VII-VII illustrating a package lid constructed in accordance with another embodiment of the invention.

FIG. 9 illustrates process steps for fabricating a packaged semiconductor in accordance with an embodiment of the invention.

### DETAILED DESCRIPTION OF PREFERRED EMBODIMENTS

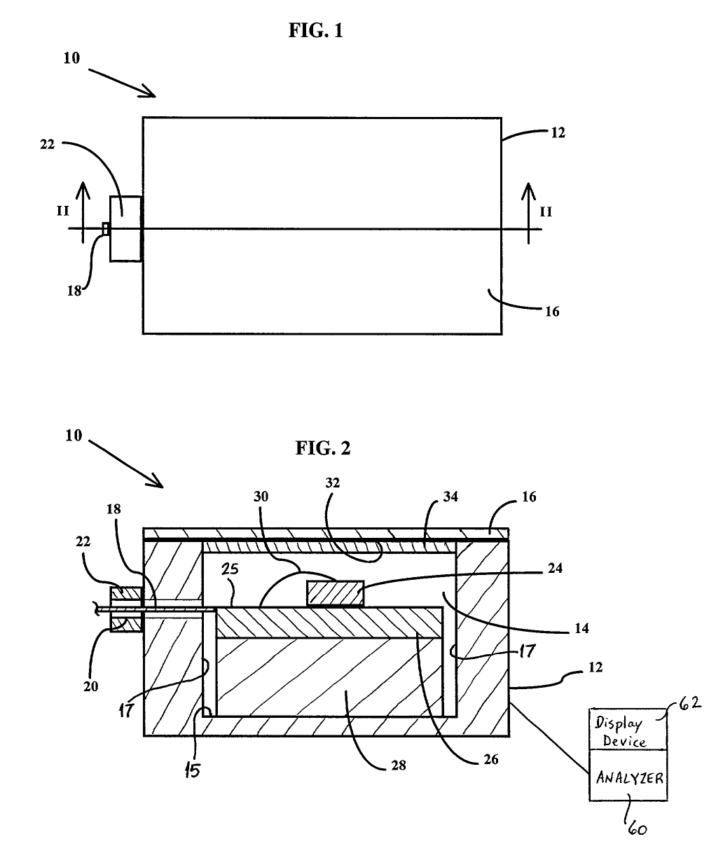

Referring now to FIGS. 1-2, there is illustrated a semiconductor package 10 which includes a package body 12, a removable package lid 16, a semiconductor chip or die 24, a submount 26, a TEC device 28 (shown schematically), a high speed connector 18, and a conduit 22. The conduit 22 is positioned on an external surface of the package body 12.

The TEC device 28, submount 26, and die 24 are positioned within a cavity 14 of the package body 12. Specifically, the TEC device 28 is anchored to a lower wall 15 of the cavity 14. The submount 26 is physically coupled to an upper portion of the TEC device 28. The die 24 is physically coupled to an upper portion 25 of the submount 26. Further, the die 24 is electrically coupled, by way of a connector 30, to a coplanar waveguide (not shown) on an upper portion 25 of the submount 26. The high speed connector 18 extends from the coplanar waveguide out of the cavity 14 through a channel 20 of the conduit 22.

The submount is preferably formed of a thermally conductive electrically insulating material, such as, for example, beryllium oxide. The TEC device 28 is a thermoelectric cooler which actively provides sufficient cooling based upon the dynamic characteristics of the die 24. As an example, the optical performance output of an optoelectric die, such as the die 24, changes over time and with temperature variations. As an output signal of the die 24 changes with time and temperature, the TEC device 28 is able to alter its cooling characteristics to provide optimum cooling to place the output signal within desired specifications.

The lower wall 15 and interior side walls 17 of the cavity 14 may be coated with an RF resonance dampening material. The RF resonance dampening material may be applied as a viscous liquid, such as an epoxy, which creates ease of application to the interior side walls 17 and the lower wall 15.

The lid 16, which is removable from the package body 12, includes an undersurface 32. An RF resonance suppressing material 34 is attached to the undersurface 32. By attaching the material 34 to a removable structure, e.g. the lid 16, the RF performance of the semiconductor package 10 can be measured with the lid 16 in place and the material 34 can be easily altered prior to its curing and without removing the die 24, submount 26, and TEC device 28. Measurement of the RF performance may be accomplished by electrically biasing the die 14 and analyzing the output of the die 14 to determine its speed and/or other desired operating characteristics. An analyzer 60 (FIG. 2), including a display device 62, is used to analyze the output and show the effectiveness of resonance dampening. Thus, the display device 62 indicates acceptable dampening or a need to alter the material 34.

Alteration of the material 34 may be accomplished in various ways. For example, alteration of the material 34 may be accomplished by removing the lid 16 and replacing it with another lid 16. Alternatively, the lid 16 may be removed and the material 34 may be altered right on the lid or removed and replaced by a second material 34. The various changes that may be exacted on the material 34 will be further discussed below. By altering the material 34 in this way, the RF performance of the semiconductor package 10 can be retested in real time, thus allowing an optional RF resonance suppression system to be put in place around the package 10 in real time. Once an acceptable RF resonance suppression is obtained, the material 34 is cured and the lid 16 is sealed.

The material 34 is preferably a material which is easily applied to the lid 16 and which is readily formable and repatternable thereon, such as a viscous epoxy. While the material 34 has been illustrated as patternless, the material may be patterned, as will now be discussed.

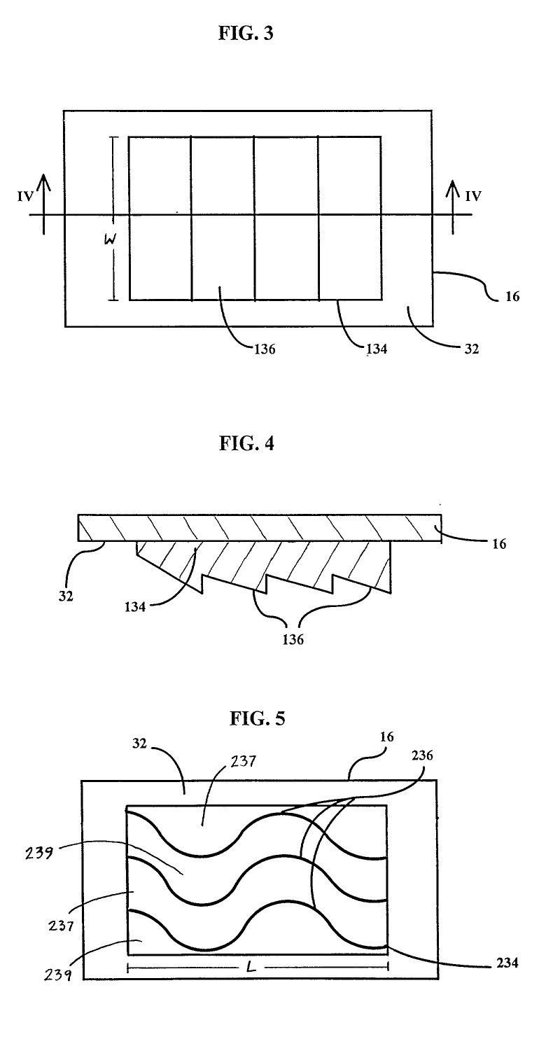

FIGS. 3-4 illustrate a material 134 which has been three-dimensionally patterned. The pattern includes an inclined surface 136 and a ledge 137 which form a saw-tooth profile. The material 134 is similar to the material 34, with the exception that the material 134 includes the three-dimensional pattern. Each inclined surface 136 is shown extending the width W of the material 134, although the inclined surfaces may not all extend the full width W.

FIG. 5 illustrates a material 234, which is similar to the material 134, except that the material 234 has a two-dimensional sinuous pattern 236 instead of the three-dimensional saw-tooth pattern. The sinuous pattern 236 may extend the length L of the material 234. The sinuous pattern 236 may be obtained by applying the material 234 to the lid 16 in alternating sections 237, 239. Further, the material 234 may be formulated with various different dopants used in various sections of on the undersurface 32 of the lid 16. For example, a carbon-doped material 234 may be used in the sections 237 and a silicon-doped material 234 may be used in the sections 239. The carbon-doped and silicon-doped sections 237, 239 may be doped to provide different degrees of resonance reflection suppression.

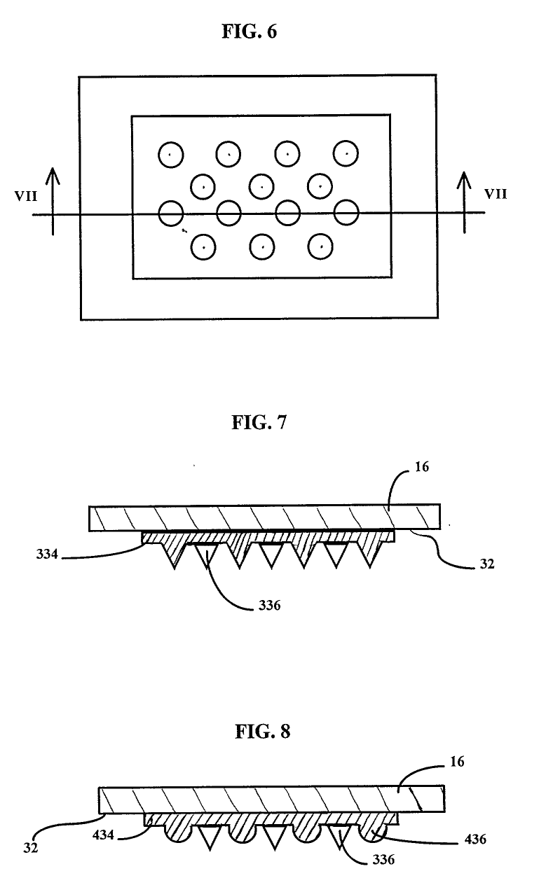

FIGS. 6-8 illustrate various other patterns of RF resonance dampening material which can be used. Specifically, a material 334 may be coated onto the lid 16 and patterned into cones 336 (FIG. 7). Alternatively, a material 434 may be coated onto the lid 16 and patterned into bumps 436. In addition, both cones 336 and bumps 436 may be patterned in the material in alternating arrangement.

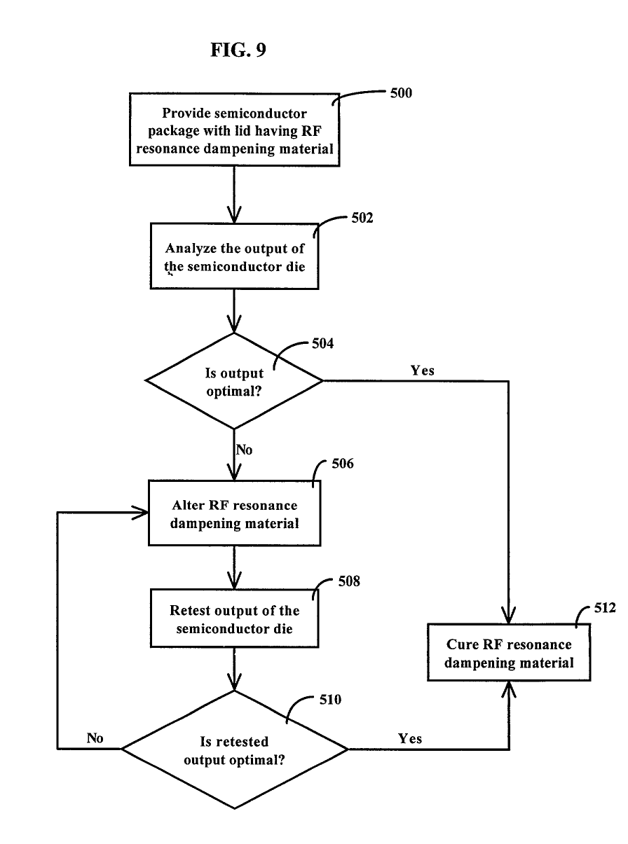

Next will be described, with reference to FIG. 9, a method for optimizing the output of a semiconductor die, such as the die 24. At step 500, the semiconductor package body 12 is provided with a lid 16 including an RF resonance dampening material, such as the material 34. The output of the die 24 is analyzed by the analyzer 60 at step 502. A decisional step occurs at step 504, namely whether the tested output is acceptable or not acceptable. If it is acceptable, then the material 34 can be cured (step 512). If instead the display device 62 indicates an unacceptable level of performance output of the die 24, the material 34 can be altered at step 506. The alteration may come in several forms. The lid 16 can be replaced by a second lid 16 having a material which has a different resistivity to resonance reflection, or the lid 16 can be removed and the material 34 thereon can be altered. The alteration can take the form of the addition of structures within the material, such as the inclined surfaces 136 and ledges 137 forming a saw-tooth profile, the two-dimensional sinuous pattern 236, the cones 336, the bumps 436, or other suitable structures. At step 508, the output of the die is retested. A decisional step occurs at step 510, namely whether the retested output is still unacceptable. If it is, step 506 can be repeated as necessary. If an acceptable output has been achieved, the RF resonance suppression material is then cured at step 512.

While the invention has been described in detail in connection with the preferred embodiments known at the time, it should be readily understood that the invention is not limited to such disclosed embodiments. Rather, the invention can be modified to incorporate any number of variations, alterations, substitutions or equivalent arrangements not heretofore described, but which are commensurate with the spirit and scope of the invention. For example, although waves, cones and bumps have been illustrated, any suitable structure may be patterned in the material 34-434, such as, for example, cubes, pyramids, or amorphous undefined structures. Accordingly, the invention is not to be seen as limited by the foregoing description, but is only limited by the scope of the appended claims.

What is claimed as new and desired to be protected by Letters Patent of the United States is:

1. A semiconductor package, comprising:
a package body having a cavity, a die being located within said cavity; and
a package lid for closing said cavity, said lid having a radio frequency resonance dampening material applied to an undersurface thereof.

2. The semiconductor package of claim 1, further comprising a submount, wherein said die is mounted on said submount.

3. The semiconductor package of claim 2, further comprising a thermoelectric cooling device upon which said submount is mounted.

4. The semiconductor package of claim 1, wherein said dampening material is alterable.

5. The semiconductor package of claim 1, wherein said material is chosen to suppress resonance reflection within said cavity.

6. The semiconductor package of claim 5, wherein said material comprises an epoxy.

7. The semiconductor package of claim 5, wherein said material is patterned.

8. The semiconductor package of claim 7, wherein said material contains a two-dimensional sinuous pattern.

9. The semiconductor package of claim 7, wherein said material contains two or more sections, at least two of said sections having different degrees of resonance reflection suppression.

10. The semiconductor package of claim 9, wherein said material contains at least one carbon-doped material section and at least one silicon-doped material section.

11. The semiconductor package of claim 7, wherein said material contains three-dimensionally patterned structures.

12. The semiconductor of claim 11, wherein said patterned structures comprise one or more of the group consisting of cones, inclined surfaces and ledges, bumps, pyramids, or cubes.

13. A semiconductor package, comprising:
a package body having a cavity;
a thermoelectric cooling device positioned within said cavity;
a submount positioned on said thermoelectric cooling device;
a die coupled to said submount; and
a package lid, wherein said lid includes a radio frequency resonance dampening material applied to an undersurface thereof, said material inhibiting resonance reflection within said cavity.

14. The semiconductor package of claim 13, wherein said material is patterned in a two-dimensional sinuous pattern.

15. The semiconductor of claim 13, wherein said material is patterned and contains two or more sections, at least two of said sections having different degrees of resonance reflection suppression.

16. The semiconductor of claim 15, wherein said material contains at least one carbon-doped material section and at least one silicon-doped material section.

17. The semiconductor of claim 13, wherein said material is patterned and contains three-dimensionally patterned structures.

18. The semiconductor package of claim 13, wherein said submount comprises beryllium oxide.

19. The semiconductor package of claim 13, wherein said material comprises an epoxy.

20. The semiconductor package of claim 13, wherein said dampening material is alterable.
